(19) United States
(12) Patent Application Publication
(10) Pub. No.: US 2020/0109867 A1
(43) Pub. Date: Apr. 9, 2020

(54) BRACKET WITH FLEXIBLE GROUNDING STRAP FOR AIR CONDITIONER UNIT

(71) Applicant: Haier US Appliance Solutions, Inc., Wilmington, DE (US)

(72) Inventor: Wilbur Carl Bewley, JR., Nicholasville, KY (US)

(21) Appl. No.: 16/154,821

(22) Filed: Oct. 9, 2018

(51) Int. Cl. F24F 1/02; F24F 13/32; H05K 5/02

(52) U.S. Cl. CPC F24F 1/027; H05K 5/0247; F24F 13/32

(57) ABSTRACT

An air conditioner unit and bracket for receiving a capacitor are provided. In one exemplary aspect, the air conditioner unit includes a bulkhead that defines an indoor portion and an outdoor portion of the unit. A wall of the bulkhead defines an opening that is accessible from the outdoor portion of the unit and is sized to allow a capacitor to be inserted therethrough. The bracket has a body that defines a mounting opening and has a grounding strap projecting from the body. The grounding strap projects vertically downward and inwardly toward a vertical centerline that extends through the center of the mounting opening. When the capacitor is received within the mounting opening, the grounding strap retains and electrically grounds the capacitor.

### FIELD OF THE INVENTION

The present disclosure relates generally to air conditioner units.

### BACKGROUND OF THE INVENTION

Air conditioner or conditioning units are conventionally utilized to adjust the temperature indoors, e.g., within structures such as dwellings and office buildings. Some types of air conditioning units are specifically designed to condition air within relatively smaller indoor spaces. For example, such air conditioner units may include packaged terminal units including packaged terminal air conditioner units (PTAC) and packaged terminal heat pumps (PTHP), single package vertical units (SPVU) including single package vertical air conditioners (SPVAC) and single package vertical heat pumps (SPVHP), built ins, and window units. Such units may include both an indoor portion and an outdoor portion separated by a bulkhead and may be installed in windows or positioned within an opening of an exterior wall of a building, for example.

Assembly and servicing of such air conditioner units has presented a number of challenges. For instance, accessing the control board, electrical wires and connectors, and the capacitor within a control box enclosure defined by the bulkhead has proved to be particularly challenging. Conventional units typically include access to the control box enclosure through the indoor or front portion of the unit. Thus, to access the components within the back of the control box enclosure, the cover of the control box and the components at the front of the control box enclosure must be removed or placed aside so that the components at the back of the enclosure may be accessed. Thus, accessing components within the control box enclosure may be inconvenient and difficult.

Further, assembling components, particularly the capacitor and other outdoor portion components, into the control box enclosure has also proved to be challenging. Bulkheads are typically assembled such that the control board, the electrical wires and connectors, and the capacitor are assembled at one time within the control box enclosure. Accordingly, when the bulkhead is assembled with the main assembly of the unit, the bulkhead must be matched with the correct voltage unit (e.g., 230V or 265V) so that the capacitor and main board are properly configured to handle the requirements of the unit. This necessitates the need to have many different bulkhead configurations. Designing and manufacturing different bulkhead configurations may be an inefficient use of resources and may make assembly more difficult. Further, current mounting brackets for capacitors require the use of fasteners to secure the capacitor to the mounting bracket. Further mounting such capacitors within the bracket may be challenging as the components with the control box enclosure are typically assembled with the bulkhead laid on its side. That is, the capacitors are not typically vertically mounted thus making assembly of the capacitor more difficult.

Accordingly, improved air conditioner units and brackets that address one or more of the challenges noted above would be useful.

### BRIEF DESCRIPTION OF THE INVENTION

Aspects and advantages of the invention will be set forth in part in the following description, may be obvious from the description, or may be learned through practice of the invention.

In accordance with one embodiment, an air conditioner unit is provided. The air conditioner unit defines a vertical direction, a lateral direction, and a transverse direction. The air conditioner unit includes a bulkhead defining an indoor portion and an outdoor portion, the bulkhead having a wall defining an opening. Further, the air conditioner unit includes a capacitor insertable through the opening defined by the wall of the bulkhead. Moreover, the air conditioner unit includes a bracket mounted to the bulkhead. The bracket includes a body defining a mounting opening in which the capacitor is mounted, the mounting opening having a center through which a vertical centerline extends along the vertical direction. The bracket also includes a grounding strap projecting from the body along the vertical direction and inwardly toward the vertical centerline such that the grounding strap retains and electrically grounds the capacitor.

In accordance with another embodiment, a bracket configured for receiving a capacitor of an air conditioner unit is provided. The bracket has a body defining a mounting opening in which the capacitor is received, the mounting opening having a center through which a vertical centerline extends along a vertical direction. The bracket also has a grounding strap extending between a proximal end connecting the grounding strap to the body and a distal end spaced from the body, wherein the grounding strap projects from the body along the vertical direction and inwardly toward the vertical centerline such that the distal end is positioned inward of the proximal end with respect to the vertical centerline.

These and other features, aspects and advantages of the present invention will become better understood with reference to the following description and appended claims. The accompanying drawings, which are incorporated in and constitute a part of this specification, illustrate embodiments of the invention and, together with the description, serve to explain the principles of the invention.

### BRIEF DESCRIPTION OF THE DRAWINGS

A full and enabling disclosure of the present invention, including the best mode thereof, directed to one of ordinary skill in the art, is set forth in the specification, which makes reference to the appended figures in which:

FIG. 1 provides a perspective view of an air conditioner unit, with part of an indoor portion exploded from a remainder of the air conditioner unit for illustrative purposes, in accordance with one exemplary embodiment of the present disclosure;

FIG. 2 provides a perspective view of components of an indoor portion of an air conditioner unit in accordance with one exemplary embodiment of the present disclosure;

FIG. 3 provides a schematic view of a refrigeration loop in accordance with one embodiment of the present disclosure;

FIG. 4 provides a rear perspective view of a bulkhead of the air conditioner unit of FIG. 1;

FIG. 5 provides a close up, exploded perspective view of a capacitor being mounted to a bracket within an enclosure in accordance with one embodiment of the present disclosure;

FIG. 6 provides a close up, front perspective view of the capacitor of FIG. 5 mounted to the bracket within the enclosure;

FIG. 7 provides a perspective view of an exemplary bracket in accordance with one exemplary embodiment of the present disclosure;

FIG. 8 provides a bottom plan view of the exemplary bracket of FIG. 7;

FIG. 9 provides a side view of the bracket of FIG. 7;

FIG. 10 provides a front view of the bracket of FIG. 7;

FIG. 11 provides a perspective view of the bulkhead of FIG. 4;

FIG. 12 provides a close-up view of the bulkhead of FIG. 11 depicting a guide member and mounting posts; and

FIG. 13 provides a close up view of a mounting flange of the bracket of FIG. 7 received within a recess of a mounting post of the bulkhead of FIG. 4.

### DETAILED DESCRIPTION OF THE INVENTION

Reference now will be made in detail to embodiments of the invention, one or more examples of which are illustrated in the drawings. Each example is provided by way of explanation of the invention, not limitation of the invention. In fact, it will be apparent to those skilled in the art that various modifications and variations can be made in the present invention without departing from the scope or spirit of the invention. For instance, features illustrated or described as part of one embodiment can be used with another embodiment to yield a still further embodiment. Thus, it is intended that the present invention covers such modifications and variations as come within the scope of the appended claims and their equivalents.

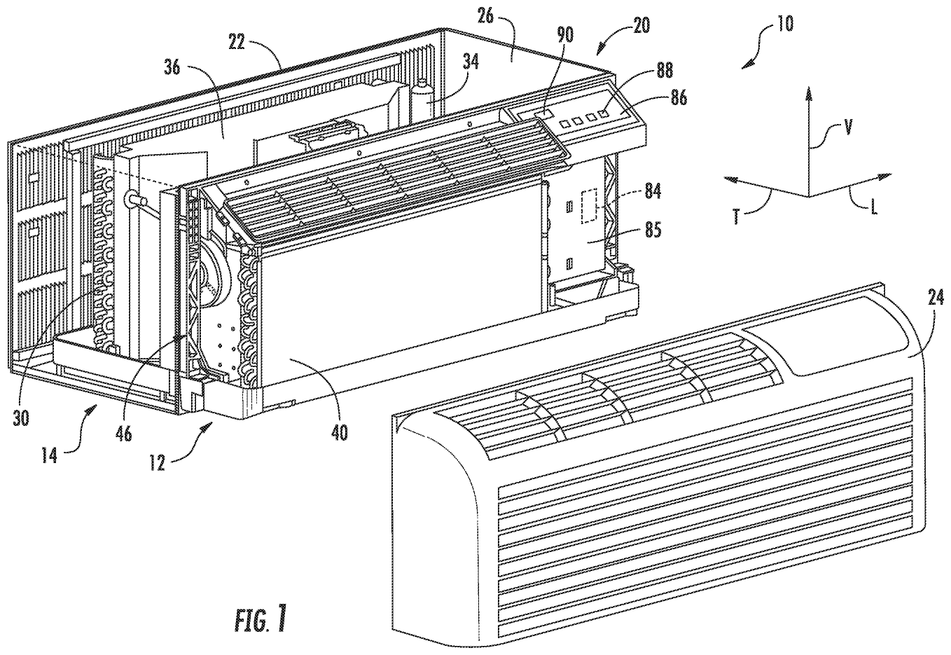

FIG. 1 provides a perspective, partially exploded view of an exemplary air conditioner unit 10. The depicted air conditioner unit 10 of FIG. 1 is a one-unit type air conditioner, also conventionally referred to as a room air conditioner or a packaged terminal air conditioner (PTAC). Although the air conditioner unit 10 of FIG. 1 is shown as a PTAC, the inventive aspects disclosed herein are applicable to air conditioning units having different configurations. For instance, the inventive aspects of the present disclosure may apply to packaged terminal units (as noted above), including PTACs and packaged terminal heat pumps (PTHP). Further, the inventive aspects may apply to single package vertical units (SPVU), including single package vertical air conditioners (SPVAC) and single package vertical heat pumps (SPVHP), built ins, window units, etc. Such units may be installed in a window, positioned within an opening of an exterior wall of a building, or some other suitable location. Moreover, for reference, air conditioner unit 10 defines a vertical direction V, a lateral direction L, and a transverse direction T. The vertical, lateral, and transverse directions V, L, T are perpendicular to each other and thus define an orthogonal coordinate system.

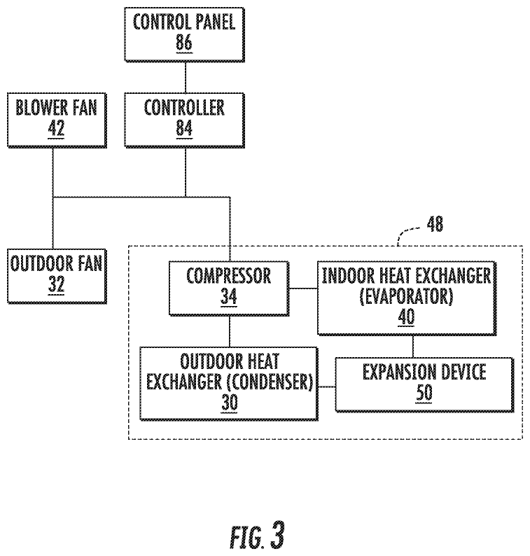

As shown in FIG. 1, air conditioner unit 10 has an indoor portion 12 and an outdoor portion 14 separated and defined by a bulkhead 46 of unit 10. Air conditioner unit 10 includes a housing 20 that contains various components. For this embodiment, housing 20 includes a rear grill 22 and a room front 24 spaced from rear grill 22 along the transverse direction T by wall sleeves 26 (only one sleeve 26 is shown in FIG. 1). Rear grill 22 is part of the outdoor portion 14 and the room front 24 may be part of the indoor portion 12. Components of the outdoor portion 14, such as an outdoor heat exchanger 30, an outdoor fan 32 (FIG. 3), and a compressor 34 may be housed within the wall sleeve 26 and between rear grill 22 and room front 24. A casing 36 encloses the outdoor fan 32.

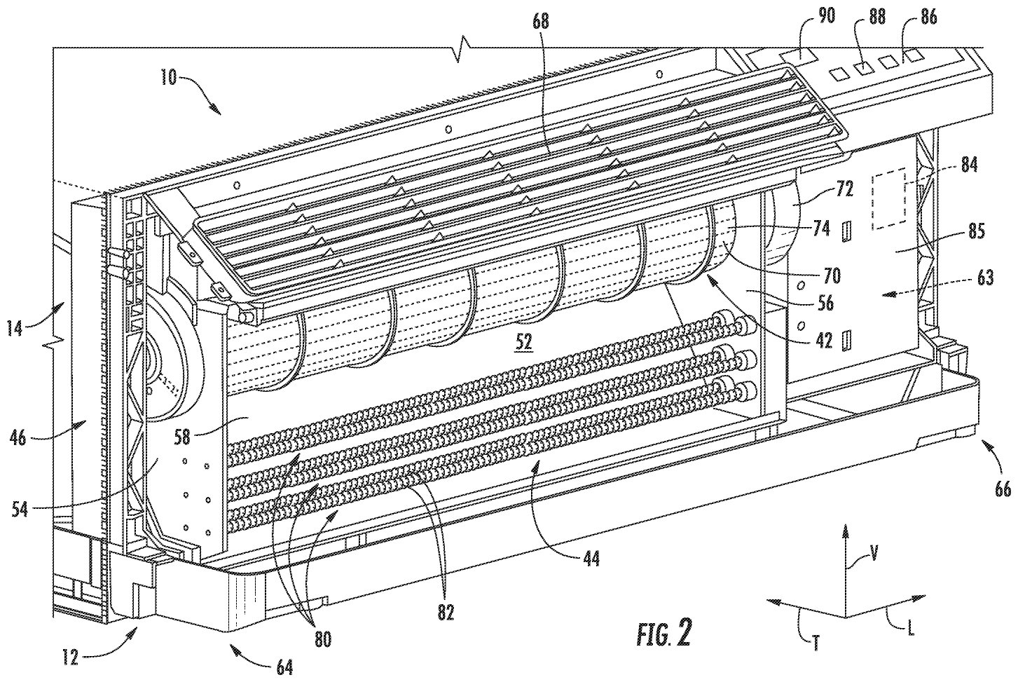

Referring now to FIGS. 1 and 2, FIG. 2 provides a perspective view of components of indoor portion 12 of air conditioner unit 10. As shown, indoor portion 12 may include an indoor heat exchanger 40 (FIG. 1), a blower fan 42 (FIG. 2), and a heating unit 44 (FIG. 2). These components may, for example, be housed behind the room front 24 (FIG. 1), which has been removed in FIG. 2 for illustrative purposes. Additionally, unit 10 includes bulkhead 46 that generally supports and/or houses various components, such as e.g., the blower fan 42, the heating unit 44, and various electronic components. Bulkhead 46 of unit 10 may generally separate and define indoor portion 12 and outdoor portion 14 of unit 10.

FIG. 3 provides a schematic view of an exemplary refrigeration loop 48 of unit 10 in accordance with one embodiment of the present disclosure. As shown, outdoor and indoor heat exchangers 30, 40 may be components of refrigeration loop 48. For this embodiment, refrigeration loop 48 includes compressor 34 and an expansion device 50. As illustrated, compressor 34 and expansion device 50 are in fluid communication with outdoor heat exchanger 30 and indoor heat exchanger 40 to flow refrigerant therethrough as is generally understood by those of skill in the art. More particularly, in some embodiments, refrigeration loop 48 may include various lines for flowing refrigerant between the various components of refrigeration loop 48 to thus provide fluid communication therebetween. Refrigerant may flow through such lines from indoor heat exchanger 40 to compressor 34, from compressor 34 to outdoor heat exchanger 30, from outdoor heat exchanger 30 to expansion device 50, and from expansion device 50 to indoor heat exchanger 40. The refrigerant may generally undergo phase changes associated with a refrigeration cycle as it flows to and through these various components, as is generally understood. One suitable refrigerant for use in refrigeration loop 48 is 1,1,1,2-Tetrafluoroethane, also known as R-134A, although it should be understood that the present disclosure is not limited to such example and that any suitable refrigerant may be utilized.

As is understood in the art, refrigeration loop 48 may be operated as a refrigeration assembly (and thus perform a refrigeration cycle) or a heat pump (and thus perform a heat pump cycle). As shown in FIG. 3, when refrigeration loop 48 is operating in a cooling mode and thus performs a refrigeration cycle, the indoor heat exchanger 40 acts as an evaporator and the outdoor heat exchanger 30 acts as a condenser. In contrast, when the assembly is operating in a heating mode and thus performing a heat pump cycle, the indoor heat exchanger 40 acts as a condenser and the outdoor heat exchanger 30 acts as an evaporator. The outdoor and indoor heat exchangers 30, 40 may each include coils through which a refrigerant may flow for heat exchange purposes, as is generally understood.

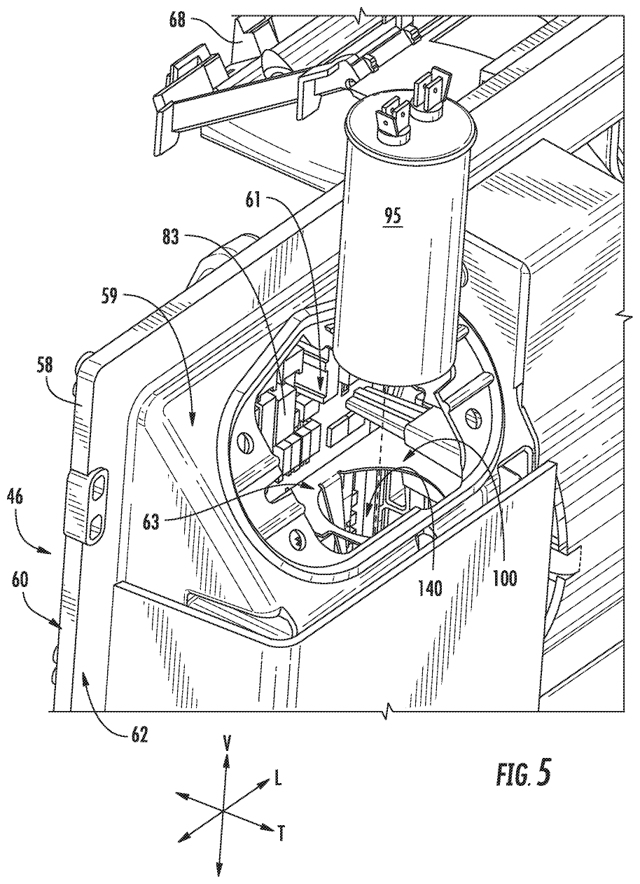

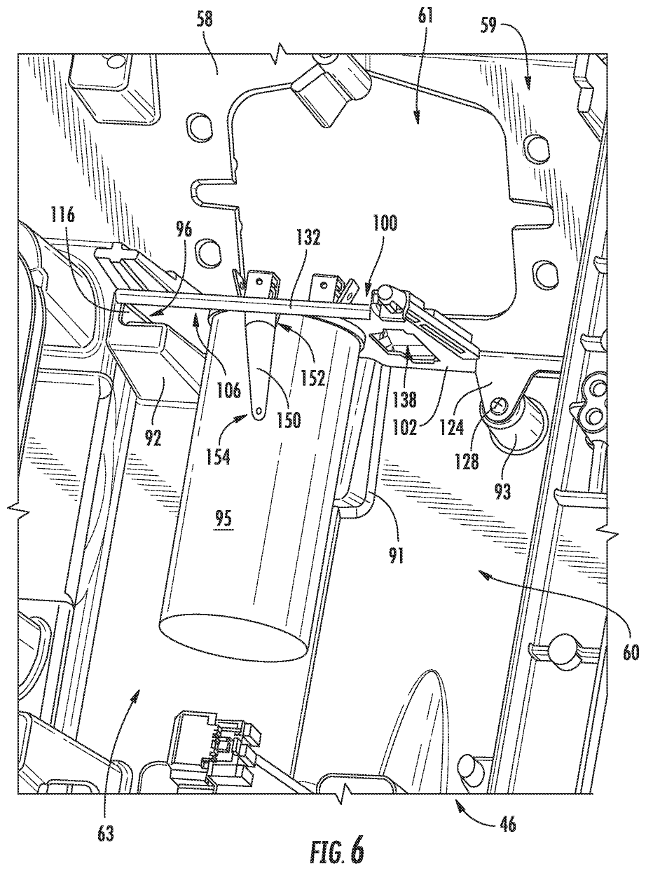

In some embodiments, compressor 34 is a variable speed compressor. In this regard, compressor 34 may be operated at various speeds depending on the current air conditioning needs of the room and the demand from refrigeration loop 48. For example, according to an exemplary embodiment, compressor 34 may be configured to operate at any speed between a minimum speed, e.g., 1500 revolutions per minute (RPM), to a maximum rated speed, e.g., 3500 RPM. Notably, use of variable speed compressor 34 enables efficient operation of refrigeration loop 48 (and thus air conditioner unit 10), minimizes unnecessary noise when compressor 34 does not need to operate at full speed, and ensures a comfortable environment within the room. In some embodiments, a capacitor 95 (FIGS. 5 and 6) is electrically coupled or connected with compressor 34 (or a motor thereof) and is configured to send one more pulses to jolt or start up compressor 34. Further, in some embodiments, capacitor 95 is configured to send a series of pulses or jolts to keep compressor 34 running during operation or execution of a thermal cycle.

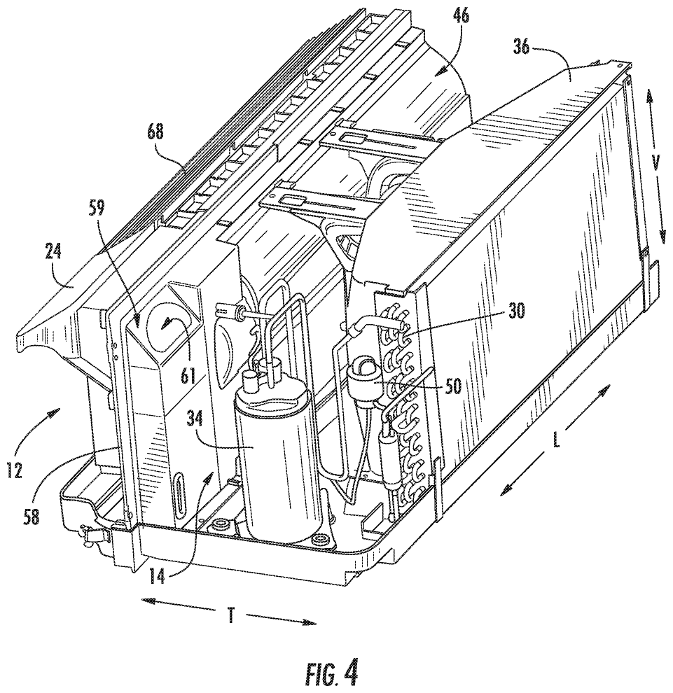

Expansion device 50 may be disposed in the outdoor portion 14 (as shown in FIG. 4) between the indoor heat exchanger 40 (FIG. 1) and the outdoor heat exchanger 30. In some embodiments, expansion device 50 is an electronic expansion valve that enables controlled expansion of refrigerant, as is known in the art. More specifically, electronic expansion device 50 may be configured to precisely control the expansion of the refrigerant to maintain, for example, a desired temperature differential of the refrigerant across the indoor heat exchanger 40. In other words, electronic expansion device 50 throttles the flow of refrigerant based on the reaction of the temperature differential across indoor heat exchanger 40 or the amount of superheat temperature differential, thereby ensuring that the refrigerant is in the gaseous state entering compressor 34. According to alternative embodiments, expansion device 50 may be a capillary tube or another suitable expansion device configured for use in a thermodynamic cycle.

Referring again to FIG. 2, as shown, bulkhead 46 accommodates a portion of blower fan 42, which may be a centrifugal fan. Alternatively, however, any suitable fan type may be utilized. Blower fan 42 may include a blade assembly 70 and a motor 72. The blade assembly 70, which may include one or more blades disposed within a fan housing 74, may be disposed at least partially within bulkhead 46. As depicted, blade assembly 70 may extend along the lateral direction L between a first sidewall 54 and a second sidewall 56. The motor 72 may be connected to the blade assembly 70, such as through housing 74 to the blades via a shaft. Operation of motor 72 may rotate the blades, thus generally operating blower fan 42. Further, in some exemplary embodiments, motor 72 may be disposed exterior to bulkhead 46. Accordingly, the shaft may extend through second sidewall 56 to connect motor 72 and blade assembly 70.

In some embodiments, outdoor fan 32 (FIG. 3) and blower fan 42 are variable speed fans. For example, motor 72 of blower fan 42 may be configured to rotate blade assembly 70 at different rotational speeds, thereby generating different airflow rates through blower fan 42. Likewise, although not shown, outdoor fan 32 may be operatively coupled with a motor that is configured to drive outdoor fan 32. It may be desirable to operate fans 32, 42 at less than their maximum rated speed to ensure safe and proper operation of refrigeration loop 48 (FIG. 3) at less than its maximum rated speed, e.g., to reduce noise when full speed operation is not needed. In some embodiments, capacitor 95 (FIGS. 5 and 6) is electrically coupled or connected with motor 72 and/or the outdoor fan motor for driving the fans 32, 42 and is configured to send one more pulses to jolt or start up the respective motors. Further, in some embodiments, capacitor 95 is configured to send a series of pulses or jolts to keep the motors running during operation or execution of a thermal cycle. Blower fan 42 may operate as an evaporator fan in refrigeration loop 48 (FIG. 3) to encourage the flow of air through indoor heat exchanger 40 (FIG. 1). Accordingly, blower fan 42 may be positioned downstream of indoor heat exchanger 40 along the flow direction of indoor air and downstream of heating unit 44 along the flow direction of outdoor air. Alternatively, blower fan 42 may be positioned upstream of indoor heat exchanger 40 along the flow direction of indoor air, and may operate to push air through indoor heat exchanger 40.

For this embodiment, heating unit 44 includes one or more heater banks 80. Each heater bank 80 may be operated as desired to produce heat. In some embodiments, as shown, three (3) heater banks 80 may be utilized. Alternatively, however, any suitable number of heater banks 80 may be utilized. Each heater bank 80 may further include at least one heater coil or coil pass 82. Alternatively, other suitable heating elements may be utilized.

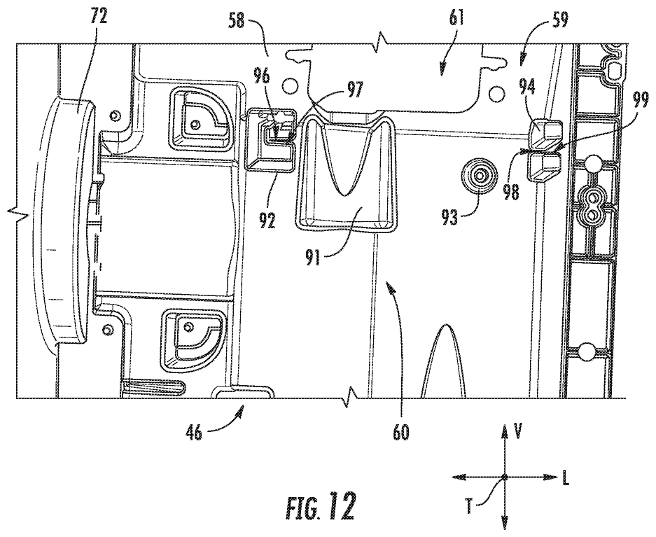

With reference still to FIG. 2, various features of bulkhead 46 will be more particularly described. As shown, bulkhead 46 extends between a first side 64 (e.g., a left side) and a second side 66 (e.g., a right side) along the lateral direction L and between a top 65 and a bottom 67 along the vertical direction V. Bulkhead 46 includes a partition wall 58 that partitions indoor portion 12 from outdoor portion 14. Partition wall 58 has an indoor surface 60 (FIG. 5) facing indoor portion 12 and an opposing outdoor surface 62 (FIG. 5) facing outdoor portion 14. Bulkhead 46 also includes various surfaces that define an interior 52 thereof. For instance, bulkhead 46 may include first sidewall 54 and second sidewall 56 spaced apart from each other along the lateral direction L. Partition wall 58 extends laterally between the first and second sidewalls 54, 56 and extends to second side 66 of bulkhead 46 (as shown best in FIG. 11). Bulkhead 46 may additionally include an air diverter 68 that extends between the first and second sidewalls 54, 56 along the lateral direction L and which may flow air therethrough.

Operation of air conditioner unit 10, including compressor 34 (and thus refrigeration loop 48 generally (FIG. 3)), blower fan 42, outdoor fan 32 (FIG. 3), heating unit 44, expansion device 50, and other components of refrigeration loop 48 may be controlled by a processing device, such as e.g., a controller 84. Controller 84 may be in communication (via for example a suitable wired or wireless connection) with such components of air conditioner unit 10. By way of example, controller 84 may include a memory and one or more processing devices such as microprocessors, CPUs or the like, such as general or special purpose microprocessors operable to execute programming instructions or micro-control code associated with operation of unit 10. The memory may represent random access memory such as DRAM, or read only memory such as ROM or FLASH. In one embodiment, the processor executes programming instructions stored in memory. The memory may be a separate component from the processor or may be included onboard within the processor. Controller 84 may be positioned within a control box enclosure 63 defined between a removable panel 85 and partition wall 58. Further, controller 84 may be one component of many electrical components of control board 83 (FIG. 5).

As shown further in FIG. 2, unit 10 may additionally include a control panel 86 and one or more user inputs 88, which may be included in control panel 86. The user inputs 88 may be in communication with controller 84. A user of the unit 10 may interact with the user inputs 88 to operate unit 10, and user commands may be transmitted between the user inputs 88 and controller 84 to facilitate operation of the unit 10 based on such user commands. A display 90 may additionally be provided in control panel 86, and may be in communication with controller 84. Display 90 may, for example be a touchscreen or other text-readable display screen, or alternatively may simply be a light that can be activated and deactivated as required to provide an indication of an event or setting for the unit 10, for example.

FIGS. 4, 5, and 6 provide various views of bulkhead 46. In particular, FIG. 4 provides a rear perspective view of bulkhead 46 of air conditioner unit 10. FIG. 5 provides a close up, exploded perspective view of capacitor 95 being mounted within enclosure 63. FIG. 6 provides a close up, front perspective view of capacitor 95 mounted within enclosure 63. As shown in FIGS. 4, 5, and 6, partition wall 58 of bulkhead 46 defines an opening 61. In particular, partition wall 58 has an angled portion 59 that defines opening 61. Notably, angled portion 59 of partition wall 58 is angled with respect to the vertical direction V. For instance, for this embodiment, angled portion 59 of partition wall 58 is angled with respect to the vertical direction V by about thirty degrees (30°). In some embodiments, angled portion 59 of partition wall 58 is angled with respect to the vertical direction V by at least thirty degrees (30°). As angled portion 59 of partition wall 58 is angled with respect to the vertical direction V, opening 61 is also defined at an angle with respect to the vertical direction V, e.g., at the same angle. Advantageously, the angled opening 61 defined by angled portion 59 of partition wall 58 allows a user to more easily access enclosure 63. In this way, a user may easily and readily insert capacitor 95 through opening 61 and may mount capacitor 95 within enclosure 63. As opening 61 is at an angle with respect to the vertical direction V, the components for mounting capacitor 95 therein are more visible and mounting is made more ergonomic. Further, the positioning of the opening 61 allows for capacitor 95 to be mounted from the outdoor portion 14 or back side of unit 10 and even if removable access panel 85 (FIG. 2) is mounted on unit 10 to enclose the electronic components within enclosure 63. Accordingly, controller 84, main board 83, and other components may be assembled at one stage in the assembly process and capacitor 95 may be mounted at a later stage in the assembly process. Moreover, capacitor 95 may be mounted after bulkhead 46 is installed onto the main assembly, e.g., housing 20. Such flexibility in the assembly process may have many advantageous benefits, such as e.g., reduction in the number of bulkhead configurations.

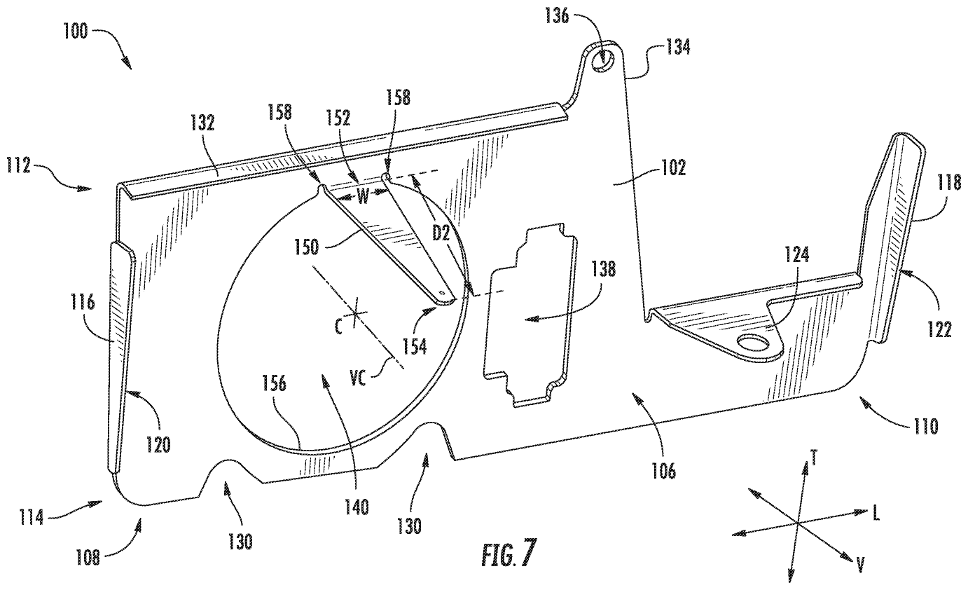

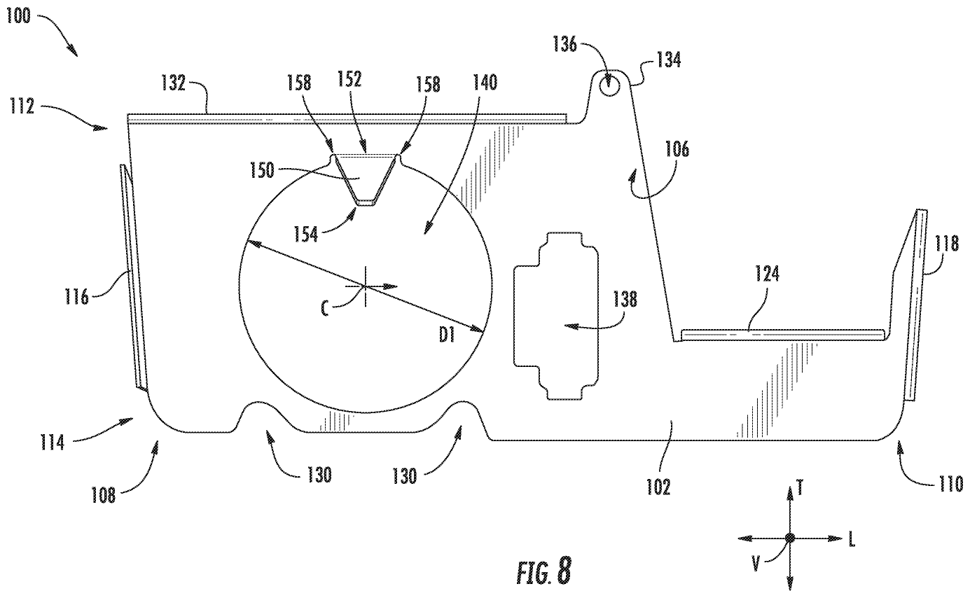

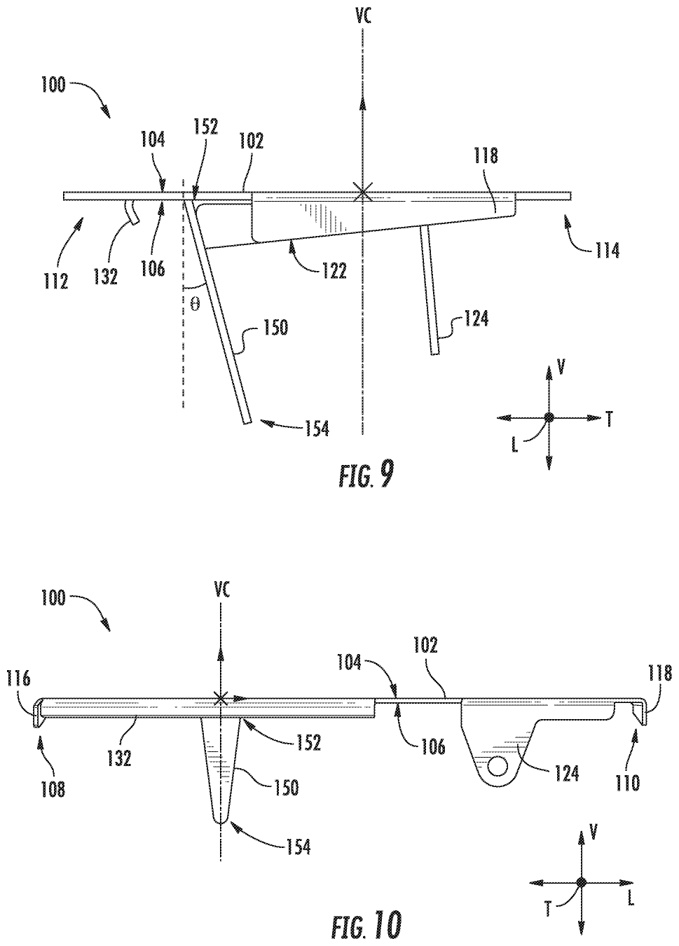

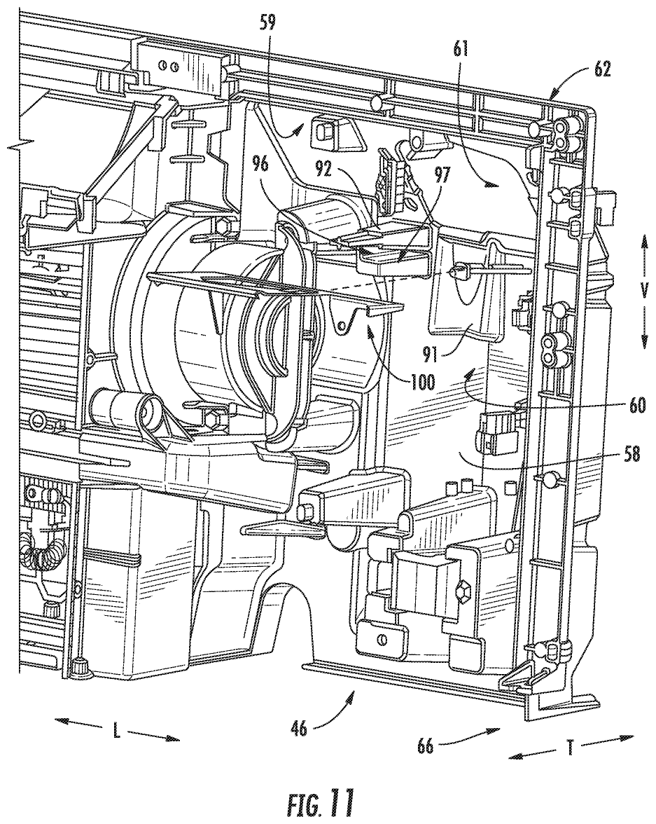

Referring now generally to FIGS. 5, 6, 7, 8, 9, and 10, various views of an exemplary bracket 100 for retaining and electrically grounding capacitor 95 (FIGS. 5 and 6) are provided. Particularly, FIG. 7 provides a perspective view of bracket 100 in accordance with one exemplary embodiment of the present disclosure. FIG. 8 provides a bottom plan view of bracket 100. FIG. 9 provides a side view of bracket 100. FIG. 10 provides a front view of bracket 100. Bracket 100 may formed of a rigid material. For instance, for this embodiment, bracket 100 is formed of cold rolled steel.

As shown best in FIGS. 7 through 10, bracket 100 includes a body 102. For this embodiment, body 102 is a generally planar plate that extends in a plane orthogonal to the vertical direction V. Body 102 has a thickness that extends along the vertical direction V. Further, as depicted best in FIGS. 9 and 10, body 102 has a top surface 104 and an opposing bottom surface 106. Body 102 extends between a first side 108 and a second side 110 along the lateral direction L and between a front 112 and a back 114 along the transverse direction T as shown best in FIG. 7.

Bracket 100 includes various features that facilitate mounting of bracket 100 to bulkhead 46. For instance, as shown, bracket 100 includes a first mounting flange 116 projecting from body 102 along the vertical direction V at first side 108. Bracket 100 also includes a second mounting flange 118 projecting from body 102 along the vertical direction V at second side 110. Notably, as shown best in FIG. 9, a bottom edge 122 of second mounting flange 118 tapers along the vertical direction V as second mounting flange 118 extends along the transverse direction T. Particularly, bottom edge 122 of second mounting flange 118 tapers upward along the vertical direction V as second mounting flange 118 extends toward back 114 along the transverse direction T. First mounting flange 116 is similarly configured. Specifically, a bottom edge 120 (FIG. 7) of first mounting flange 116 tapers upward along the vertical direction V as first mounting flange 116 extends toward back 114 along the transverse direction T. Accordingly, first mounting flange 116 and second mounting flange 118 are each wedge shaped.

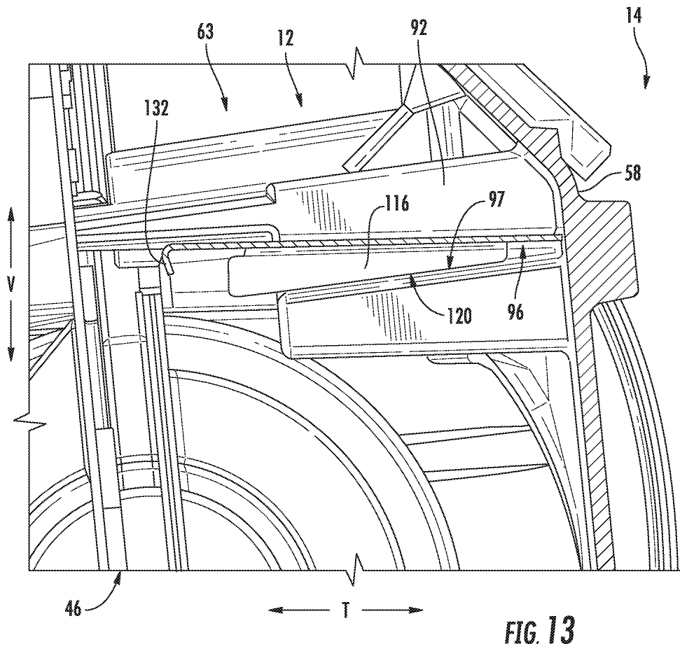

FIG. 11 provides a perspective view of second side 66 of bulkhead 46 and FIG. 12 provides a close-up view of bulkhead 46. As shown in FIGS. 11 and 12, a first post 92 projects from indoor surface 60 of bulkhead 46 along the transverse direction T, e.g., in a direction toward the front of unit 10. A second post 94 (FIG. 12) is spaced from first post 92 and projects from indoor surface 60 of bulkhead 46 along the transverse direction T, e.g., in a direction toward the front of unit 10. Particularly, second post 94 is spaced from first post 92 along the lateral direction L. First post 92 defines a first recess 96 and second post 94 defines a second recess 98 (FIG. 12). First post 92 has a ramp 97 that defines the bottom wall of first recess 96. Ramp 97 is angled or tapered complementary to the tapered, wedge shaped first mounting flange 116. Similarly, second post 94 has a ramp 99 (FIG. 12) that defines the bottom wall of second recess 98. Ramp 99 is angled or tapered complementary to the tapered, wedge shaped second mounting flange 118.

First recess 96 of first post 92 and second recess 98 of second post 94 are generally defined such that they are aligned along the vertical direction V and such that they may each receive their respective first and second mounting flanges 116, 118. To mount bracket 100 to bulkhead 46, as shown in FIG. 11, bracket 100 is slid along the transverse direction T toward indoor surface 60 of partition wall 58 such that first mounting flange 116 of bracket 100 is received within first recess 96 (as shown in FIG. 6) and second mounting flange 118 of bracket 100 is received within second recess 98. Moreover, as first and second mounting flanges 116, 118 are wedge shaped, as bracket 100 is slid toward indoor surface 60 of partition wall 58, the friction between the mounting flanges 116, 118 and the ramps 93, 95 of the first and second posts 92, 94 increases thereby securing bracket 100 to bulkhead 46. As shown in FIG. 13, first mounting flange 116 is received within first recess 96, and as depicted, bottom edge 120 of first mounting flange 116 is engaged with ramp 97 of first post 92. Second mounting flange 118 may be similarly received within second recess 98.

In addition, with reference again to FIGS. 7 through 10, bracket 100 includes a grounding flange 124 projecting from body 102. Specifically, grounding flange 124 projects downward from body 102 along the vertical direction V. Grounding flange 124 defines a hole 126 that is configured to receive a mechanical fastener therethrough, e.g., a screw. For instance, as best shown in FIG. 6, grounding flange 124 of bracket 100 is aligned with a boss 93 projecting from bulkhead 46. A screw 128 extends through hole 126 of grounding flange 124 and into boss 93 to secure bracket 100 to bulkhead 46. Notably, in some embodiments, screw 128 is electrically connected with an electrical ground. For instance, in some embodiments, a ground wire from an electrical harness may be in electrical communication with screw 128, and as screw 128 is in mating engagement with grounding flange 124 of bracket 100, bracket 100 is electrically grounded.

Bracket 100 and bulkhead 46 both include various features for aligning bracket 100 with respect to bulkhead 46. For instance, as shown in FIGS. 11 and 12, bulkhead 46 includes a guide member 91 projecting from indoor surface 60 of bulkhead 46. For this embodiment, guide member 91 projects from indoor surface 60 of partition wall 58 along the transverse direction T toward the front of air conditioner unit 10. Moreover, for this embodiment, guide member 91 has a U-shaped cross section as viewed along the vertical direction V. As shown best in FIGS. 7 and 8, bracket 100 defines one or more guide cutouts 130 for receiving the guide member 91 of bulkhead 46 for aligning bracket 100 with bulkhead 46. Particularly, body 102 of bracket 100 defines guide cutouts 130 along a back edge of bracket 100 at back 114. For this embodiment, guide cutouts 130 are shaped complementary to guide member 91. In this way, when bracket 100 is mounted to bulkhead 46 and position, the projections of guide member 91 are received within guide cutouts 130 of bracket 100. The curved surfaces of guide member 91 and guide cutouts 130 of bracket 100 allow a user to readily align bracket 100 with guide member 91 of bulkhead 46. Specifically, when guide member 91 is received within guide cutouts 130, the curved surfaces align in mating engagement thus providing a user with feedback that bracket 100 is properly aligned. It will be appreciated that guide member 91 and guide cutouts 130 may have other suitable shapes and configurations. Moreover, in some embodiments, guide member 91 may define one or more guide cutouts in which one or more projections of bracket 100 may be received, e.g., to align bracket 100 with bulkhead 46.

For this embodiment, bracket 100 includes a front flange 132 projecting from body 102 at front 112 of bracket 100. Specifically, front flange 132 projects from body 102 along the vertical direction V. Front flange 132 smooths out the front edge of body 102 and prevents electrical wires from catching or rubbing against bracket 100. Bracket 100 also includes a board support flange 134. Board support flange 134 projects from body 102 in a plane orthogonal to the vertical direction V. Board support flange 134 has rounded edges and also defines a hole 136. A fastener may extend through hole 136, e.g., to support control board 83 (FIG. 5). In addition, bracket 100 defines a pin or connector opening 138 as shown in FIGS. 7 and 8. Particularly, body 102 of bracket 100 defines connector opening 138. For this embodiment, connector opening 138 is shaped and sized to receive a pin connector (not shown) therethrough.

As shown best in FIGS. 5, 6, 7, and 8, body 102 of bracket 100 defines a mounting opening 140 that is sized and configured to receive capacitor 95 (FIGS. 5 and 6). For instance, as shown in FIG. 6, capacitor 95 is received within mounting opening 140 of bracket 100. Thus, opening 61 is shaped generally complementary to capacitor 95. In this embodiment, capacitor 95 is a cylindrical metal encased capacitor, and accordingly, mounting opening 140 is a generally circular opening so that it may accommodate capacitor 95. Mounting opening 140 has a center C (FIGS. 7 and 8) through which a vertical centerline VC extends along the vertical direction V.

As depicted, bracket 100 includes a grounding finger or strap 150 projecting from body 102. Generally, as will be explained more fully below, grounding finger 150 is configured to retain and electrically ground capacitor 95. Grounding strap 150 extends between a proximal end 152 and a distal end 154. Proximal end 152 connects grounding strap 150 to body 102 of bracket 100. Distal end 154 is spaced from body 102, e.g., along the vertical direction V. For this embodiment, grounding strap 150 projects from an edge or rim 156 of body 102 that defines mounting opening 140. Notches 158 are defined by body 102 on both sides of proximal end 152 of grounding strap 150 to facilitate movement (e.g., deflection) of grounding strap 150 and to reduce the stress along rim 156 immediately proximate where proximal end 152 of grounding strap 150 connects to body 102. Grounding strap 150 projects from a front portion of rim 156 in this exemplary embodiment. However, in alternative embodiments, grounding strap 150 may project from a back portion of rim 156, a side portion of rim 156, etc. In some embodiments, grounding strap 150 may project from body 102 from other suitable locations.

Further, as best shown in FIG. 7, grounding strap 150 has a width W. Notably, the width W gradually decreases from proximal end 152 to distal end 154. That is, grounding strap 150 tapers as it extends from its proximal end 152 to its distal end 154. The thicker width W of grounding strap 150 at proximal end 152 provides structural stability and the less thick width W of grounding strap 150 at distal end 154 provides grounding strap 150 with more flexibility to deflect when engaged by capacitor 95. The tapered configuration of grounding strap 150 allows for more deflection of distal end 154 for an applied maximum stress, e.g., compared to a non-tapered grounding strap 150. Thus, grounding strap 150 may be a constant stress beam. Moreover, as shown best in FIG. 8, mounting opening 140 of bracket 100 has a diameter D1. In some embodiments, grounding strap 150 extends a distance D2 (FIG. 7) (i.e., a distance between proximal end 152 and distal end 154) that is greater than or equal to half of the diameter D1 of mounting opening 140. For this embodiment, grounding strap 150 extends a distance D2 that is about two-thirds of the diameter D1 of mounting opening 140.

Notably, as best shown in FIG. 9, when grounding strap 150 is in a relaxed state (i.e., a state in which there is no physical load applied on or to grounding strap 150, e.g., as shown in FIGS. 7 through 10), grounding strap 150 projects from body 102 of bracket 100 along the vertical direction V and inwardly toward the vertical centerline VC such that distal end 154 is positioned inward of proximal end 152 with respect to the vertical centerline VC. That is, grounding strap 150 projects from body 102 such that distal end 154 is closer to the vertical centerline VC than proximal end 152. In some embodiments, grounding strap 150 is angled inwardly toward the vertical centerline VC by an angle theta (θ) as shown in FIG. 9. For this embodiment, grounding strap 150 projects inwardly toward the vertical centerline VC by at least five degrees (5°) with respect to the vertical direction V when grounding strap 150 is in a relaxed state. Thus, in such embodiments, the angle theta θ is at least five degrees (5°).

To mount capacitor 95 within enclosure 63 to bracket 100, capacitor 95 may be lowered along the vertical direction V and inserted through opening 61 defined by angled portion 59 of partition wall 58 as shown in FIG. 5. The capacitor 95 may be further lowered along the vertical direction V and positioned within mounting opening 140 of bracket 100. When capacitor 95 is lowered and positioned within mounting opening 140, grounding strap 150 engages capacitor 95. Particularly, grounding strap 150 engages the metal cylindrical casing of capacitor 95. Capacitor 95 applies a physical load on grounding strap 150, which causes grounding strap 150 to deflect. Thus, when capacitor 95 is lowered into mounting opening 140 and engaged by grounding strap 150, grounding strap 150 is moved to a deflected state. That is, distal end 154 of grounding strap 150 may be deflected outward and away from the vertical centerline VC when engaged by capacitor 95. In some embodiments, for example, distal end 154 of grounding strap 150 may be deflected about one hundredth of an inch (0.01 inches) with respect to its resting state position.

The deflection of grounding strap 150 causes grounding strap 150 to apply a retaining force on capacitor 95. Thus, grounding strap 150 retains capacitor 95 in position as shown best in FIG. 6. In some embodiments, grounding strap 150 is formed of a high yield strength material, e.g., steel, so that grounding strap 150 may accommodate the load or weight of capacitor 95 and retain capacitor 95 in place. Notably, no tools or fasteners are required to mount capacitor 95 to bracket 100. Capacitor 95 is lowered within mounting opening 140 of bracket 100 and grounding strap 150 automatically engages and retains capacitor 95.

Further, grounding strap 150 electrically grounds capacitor 95. That is, when capacitor 95 is inserted through mounting opening 140 of bracket 100 and engaged by grounding strap 150, grounding strap 150 automatically electrically grounds capacitor 95. As noted above, bracket 100 may be electrically ground by any suitable electrical ground, such as e.g., grounding screw 128 (FIG. 6) that is electrically ground by a ground wire of an electrical harness positioned within enclosure 63. Accordingly, a user need not make any electrical connections to ground capacitor 95 when mounting capacitor 95 to bracket 100.

In some alternative embodiments, bracket 100 may include multiple grounding straps 150 projecting from body 102. For instance, a first grounding strap may project from body 102 as shown in FIGS. 7 through 10, e.g., at a front portion of mounting opening 140. A second grounding strap may project from body 102 at a back or rear portion of mounting opening 140. The second grounding strap may be similarly configured as the first grounding strap. The first and second grounding strap may oppose one another. That is, the first and second grounding straps may be spaced from one another by one hundred eighty degrees (180°) with respect to the center C of mounting opening 140. The opposing configuration of the first and second grounding straps may facilitate vertical alignment of capacitor 95. Moreover, the additional grounding strap may further retain capacitor 95 within mounting opening 140 of bracket 100.

Air conditioner unit 10 and bracket 100 described herein provide a number of advantages and benefits. For instance, some or all of the components within enclosure 63 may be accessed and assembled from the back of bulkhead 46, which may facilitate assembly and servicing of unit 10. For example, as depicted in FIGS. 4 and 5, angled portion 59 of partition wall 58 defines opening 61 through which capacitor 95 may be inserted. Thus, capacitor 95 may be assembled into bulkhead 46 and may be accessed from outdoor portion 14 or the outdoor side of bulkhead 46. This may facilitate assembly and servicing of capacitor 95 and may provide more flexibility to the assembly process. For instance, capacitor 95 may be assembled at a later stage in the assembly process and need not be assembled within enclosure 63 at the same time as the other components. This may, for example, decrease the need for custom bulkhead configurations for each capacitor type and each voltage unit. Further, the orientation of opening 61 and configuration of bracket 100 allows capacitor 95 to be assembled vertically. In addition, bracket 100 facilitates mounting of capacitor 95 without need for tools or fasteners. As such, assembly is simplified, reliability is increased, and maintenance costs are reduced. Moreover, grounding strap 150 of bracket 100 automatically retains and electrically grounds capacitor 95 when capacitor 95 is inserted within mounting opening 140 of bracket 100. This may, for example, further facilitate ease of assembly and efficiency. Furthermore, those of skill in the art will appreciate that air conditioner unit 10 and bracket 100 may provide other advantages and have other benefits not expressly listed herein.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

What is claimed is:

1. An air conditioner unit defining a vertical direction, a lateral direction, and a transverse direction, the air conditioner unit comprising:
a bulkhead defining an indoor portion and an outdoor portion, the bulkhead having a wall defining an opening;
a capacitor insertable through the opening defined by the wall of the bulkhead;
a bracket mounted to the bulkhead, the bracket comprising:
a body defining a mounting opening in which the capacitor is mounted, the mounting opening having a center through which a vertical centerline extends along the vertical direction;
a grounding strap projecting from the body along the vertical direction and inwardly toward the vertical centerline such that the grounding strap retains and electrically grounds the capacitor.

2. The air conditioner unit of claim 1, wherein the grounding strap projects inwardly toward the vertical centerline by at least five degrees (5°) with respect to the vertical direction.

3. The air conditioner unit of claim 1, wherein the mounting opening is defined by a rim of the body, and wherein the grounding strap projects from the rim.

4. The air conditioner unit of claim 1, wherein the mounting opening of the bracket has a diameter, and wherein the grounding strap extends a distance that is greater than or equal to half of the diameter of the mounting opening.

5. The air conditioner unit of claim 1, wherein the bracket is formed of cold rolled steel.

6. The air conditioner unit of claim 1, wherein the bracket extends between a first side and a second side along the lateral direction, and wherein the bracket further comprises a first mounting flange projecting from the body along the vertical direction at the first side and a second mounting flange projecting from the body along the vertical direction at the second side.

7. The air conditioner unit of claim 6, wherein the wall of the bulkhead has an indoor surface and an outdoor surface, and wherein a first post projects from the indoor surface along the transverse direction and a second post spaced from the first post projects from the indoor surface of the bulkhead along the transverse direction, and wherein the first post defines a first recess in which the first mounting flange of the bracket is received and the second post defines a second recess in which the second mounting flange of the bracket is received.

8. The air conditioner unit of claim 1, wherein the bracket further comprises a grounding flange projecting from the body, wherein the grounding flange defines a hole through which a screw extends to secure the bracket to the bulkhead, and wherein the screw is electrically grounded.

9. The air conditioner unit of claim 1, wherein the wall of the bulkhead has an angled portion that is angled with respect to the vertical direction, and wherein the angled portion of the wall defines the opening.

10. The air conditioner unit of claim 9, wherein the angled portion of the wall is angled with respect to the vertical direction by at least thirty degrees (30°).

11. The air conditioner unit of claim 1, further comprising:
a removable panel mounted to the bulkhead such that the removable panel and the wall define an enclosure in which the bracket is mounted to the bulkhead, and wherein the opening defined by the wall provides access to the enclosure from the outdoor portion of the air conditioner unit.

12. The air conditioner unit of claim 1, wherein the wall of the bulkhead has an indoor surface and an outdoor surface, and wherein a guide member projects from the indoor surface of the bulkhead, and wherein the bracket defines one or more guide cutouts for receiving the guide member of the bulkhead for aligning the bracket with the bulkhead.

13. The air conditioner unit of claim 1, wherein the capacitor is a cylindrical metal encased capacitor.

14. The air conditioner unit of claim 1, wherein the grounding strap extends between a proximal end connecting the grounding strap to the body and a distal end spaced from the body, and wherein the body defines notches on both sides of the proximal end of the grounding strap.

15. A bracket configured for receiving a capacitor of an air conditioner unit, the bracket comprising:
a body defining a mounting opening in which the capacitor is received, the mounting opening having a center through which a vertical centerline extends along a vertical direction;
a grounding strap extending between a proximal end connecting the grounding strap to the body and a distal end spaced from the body, wherein the grounding strap projects from the body along the vertical direction and inwardly toward the vertical centerline such that the distal end is positioned inward of the proximal end with respect to the vertical centerline.

16. The bracket of claim 15, wherein the distal end of the grounding strap retains and electrically grounds the capacitor when the capacitor is received within the mounting opening.

17. The bracket of claim 15, wherein the bracket defines a lateral direction and a transverse direction perpendicular to the lateral direction and the vertical direction, and wherein the bracket extends between a first side and a second side along the lateral direction and between a front and a back along the transverse direction, and wherein the bracket further comprises a first mounting flange projecting from the body along the transverse direction and the vertical direction at the first side and a second mounting flange projecting from the body along the transverse direction and the vertical direction at the second side, and wherein the first mounting flange tapers along the vertical direction as the first mounting flange extends along the transverse direction and the second mounting flange tapers along the vertical direction as the second mounting flange extends along the transverse direction.

18. The bracket of claim 17, wherein the first mounting flange tapers upward along the vertical direction as the first mounting flange extends toward the back along the transverse direction and wherein the second mounting flange tapers upward along the vertical direction as the second mounting flange extends toward the back along the transverse direction.

19. The bracket of claim 15, wherein the grounding strap has a width, and wherein the width gradually decreases from the proximal end to the distal end.
